(19) United States
(12) Patent Application Publication
(10) Pub. No.: US 2002/0181189 A1
(43) Pub. Date: Dec. 5, 2002

(54) Notebook computer with a small display panel

(76) Inventor: Tzu-Shiou Yang, Taipei (TW)

Correspondence Address: RABIN & BERDO, P.C., Suite 500, 1101 14th Street, N.W., Washington, DC, 20005, US

(21) Appl. No.: 10/108,427

(22) Filed: Mar. 29, 2002

(30) Foreign Application Priority Data
Jun. 4, 2001 (TW) 90209209

(51) Int. Cl. H05K 5/00

(52) U.S. Cl. 361/681; 361/680

(57) ABSTRACT

A notebook computer with a small display panel is provided. The notebook computer includes a covering board and a platform. A pivot is used to joint the covering board with the platform. The small display panel being situated on the platform displays the speed and make of the Central Processing Unit (CPU), the signal receiving status during wireless communication, the battery capacity and the dynamic instant power consumption. Which not only provides the user with instant status of the notebook computer in a glance, but also helps the user to achieve a quick grasp of instant information.

This application incorporates by reference Taiwanese application Serial No. 90209209, Filed Jun. 4, 2001.

### BACKGROUND OF THE INVENTION

1. Field of the Invention

The invention relates in general to a notebook computer, and more particularly to a notebook computer with a small display panel.

2. Description of the Related Art

In the age of technology, computer has become an indispensable appliance for modem people in their work and entertainment as well. Compared to a desktop computer, a notebook computer is lighter in weight and smaller in size. Since the notebook computer is so compact and portable, it has won great popularity with the users. Particularly the businessmen find it convenient and efficient to deal with their business matters, such as briefing and e-mailing, using a notebook computer whenever and wherever they want to.

Despite computers, the Internet and mobile phones, which have almost become a necessity to modem people in their everyday lives, are following the trend of miniaturization and mobility, the information transmission between these devices still need to be done via links, such as the link between a mobile phone, computer, camera etc., causing inconvenience to the user. The Bluebooth technology, which replaces wired connection with radio waves, provides a telecommunication environment of instant transmission of voice and data, which is free of the line impedance of wires and achieves a mutual communication of information whenever and wherever it is needed.

The Bluetooth, which provides short-distance wireless communication, encompasses three areas:

(1) Cable Replacement—The Bluetooth provides all mobile devices with wireless transmission function such as the hands-free telephone receiver in voice transmission, peripheral equipment in data transmission and control equipment in instruction transmission; the connection between devices is instant, continuous and will not be influenced by the terrain and its features;

(2) Data/Voice Access Point—The Bluetooth provides a broader application in transmission facilitating a more convenient instant voice and data transmission: the connection between a portable device and a fixed-type communication device would be as easy as switching the power; furthermore, via the access to a wired network or the Internet, the user can surf the Internet via wireless connections; and

(3) Personal Ad-Hoc Network—The Bluetooth provides a network communication environment anytime and anywhere such that the resources or files of other computers in the network can be shared; for instance, when a wireless communication device equipped with the Bluetooth enters into the area covered by another device with the same equipment, a connection between the two devices will be established soon; since the Bluetooth provides one-to-one as well as one-to-multiple connections, a number of micro networks can be established and further connected to each other forming an ad-hoc network.

From the foregoing examples and explanations disclosed, it is very clear that the Bluetooth has had far reaching influence in the mobile communication markets and products in regards to the development of computer hardware and software as well.

In recent years, many manufacturers have been devoted to the research and development of mobile phones with the Bluetooth technology to usher in an age of wireless communication. Many of the electronic related appliances including the notebook computer have also been equipped with the Bluetooth. Generally speaking, the antenna of the Bluetooth is hidden inside the notebook computer such that the outward appearance will not be influenced. The receiving device and sending device are allowed to be mobile and do not need to be aligned in direction during wireless communication, and will not be influenced by the line-of-sight between them. However, the instant sending/receiving status of radio signals, and the signal sending/receiving quality of the hidden antenna are still left unknown.

Since portability is an important appeal of the notebook computer, its battery capacity status hence becomes critical. A conventional notebook computer does not inform the user of the capacity of its rechargeable batteries: the user needs to estimate roughly how many hours of duration the rechargeable battery allows. Ageing occurs after the battery has been used and recharged over and over again, which makes it even harder for the user to estimate the available duration of the battery, hence risking data being lost or having an unexpected power suspension.

In addition, the speed of the Central Processing Unit (CPU) is only available at the time when the notebook computer is started. Furthermore, this piece of information only shows shortly and is easily to be missed: to see this information again, the user has to wait until next time when the notebook computer is started. It is indeed very inconvenient to the user. Besides, the current power consumption of the notebook computer is unavailable to the user of a conventional notebook computer.

The foregoing drawbacks cause difficulties for the user to grasp the instant status of their notebook computers.

### SUMMARY OF THE INVENTION

It is therefore an object of the invention to provide a notebook computer with a small display panel. The small display panel installed in the platform of a notebook computer displaying some instant status of the notebook computer, not only makes the instant status clear to the user in a glance, but also helps the user to achieve a quick grasp of instant information.

According to the object of the invention, a notebook computer with a small display panel comprising two parts, a platform and a covering board, is provided. A pivot is used to joint the covering board on which a screen is situated together with the platform inside which a motherboard is situated. The small display panel to which the motherboard is coupled is situated on the platform. The small display panel displays some related information of a notebook computer such as the speed and make of the CPU, sending/receiving status of wireless communication, battery capacity and dynamic instant power consumption.

### BRIEF DESCRIPTION OF THE DRAWINGS

Other objects, features, and advantages of the invention will become apparent from the following detailed description of the preferred but non-limiting embodiments. The description is made with reference to the accompanying drawings in which:

FIG. 1 shows a schematic diagram of a notebook computer with a small display panel according to a preferred embodiment of the invention.

### DESCRIPTION OF THE PREFERRED EMBODIMENT

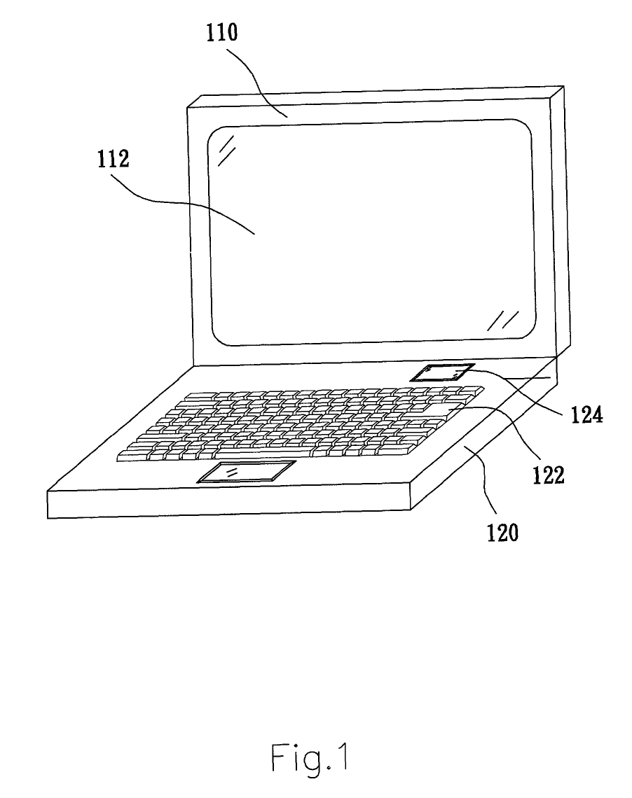

Referring to FIG. 1, a schematic diagram of a notebook computer with a small display panel according to a preferred embodiment of the invention is illustrated. The notebook computer compromises two parts: a covering board 110 and a platform 120. The covering board is jointed to the platform 120 via a pivot. A crystal screen 112 is situated on the covering board 110, while a motherboard (not shown here) is situated inside the platform 120. Apart from a keyboard 122, a small display panel 124 to which the motherboard is coupled is also installed on the platform 120. There is no limitation in relation to the location of the small display panel 124. Any small display panel as long as it achieves the display function is to be encompassed within the scope of technology disclosed in the invention.

The small display panel 124 such as a Liquid Crystal Display (LCD) can be used to display the current battery capacity of the rechargeable battery used in a notebook computer. A column indicator can be used to show the current power consuming or charging rate: for instance, an indicator with a full level indicating no power consumption or the charging has been completed. The lower the column level is, the more power has been consumed. The small display panel 124 also displays the signal receiving status of the built-in Bluetooth antenna inside a notebook computer during wireless communication. For example, the signal receiving status can be shown using an antenna symbol and a bar chart being lined up according to the height. The better radio signal receiving quality the Bluetooth antenna has, the higher the bars shown on the display will be; and the worse radio signal receiving quality the Bluetooth antenna has, the lower the bars shown on the display will be.

Apart from that, the small display panel 124 displays the ordinary and instant speed or even the make of the CPU of the notebook computer. The small display panel 124 also displays immediately the power consumption status helping the user to achieve power saving. There is no limitation regarding the ways and methods of display of the small display panel 124. Any small display panel as long as it achieves an instant display function is to be encompassed within the scope of technology disclosed in the invention.

The notebook computer with a small display panel disclosed in the foregoing preferred embodiment of the invention has the following advantages:

1. The small display panel, which instantly displays the capacity of the rechargeable battery used in the notebook computer, provides the user with thorough understanding of the current status of the rechargeable battery avoiding difficult situations of having data being lost or having an unexpected power suspension.

2. The small display panel, which instantly displays the signal receiving status of the built-in antenna of a notebook computer during wireless communication, provides a clear picture and thorough understanding to the user when doing wireless communication.

3. The small display panel, which displays the ordinary speed, instant speed and make of the CPU allowing the user to have a quick understanding of CPU status without restarting the notebook computer, provides the user with more convenience.

4. The small display panel, which displays the power consumption at a glance, helps the user to achieve power saving.

While the invention has been described by way of example and in terms of the preferred embodiment, it is to be understood that the invention is not limited to the disclosed embodiment. To the contrary, it is intended to cover various modifications and similar arrangements and procedures, and the scope of the appended claims therefore should be accorded the broadest interpretation so as to encompass all such modifications and similar arrangements and procedures.

What is claimed is:

1. A notebook computer with a small display panel, comprising:
a covering board on which a crystal screen is situated; and
a platform inside which a motherboard is situated being jointed together with the covering board via a pivot, wherein the small display panel, being situated on the platform and coupled to the motherboard, displays instantly the dynamic power consumption of the notebook computer.

2. A notebook computer with a small display panel according to claim 1, wherein the small display panel is a Liquid Crystal Display (LCD).

3. A notebook computer with a small display panel according to claim 1, wherein the small display panel displays the speed and make of the Central Processing Unit (CPU).

4. A notebook computer with a small display panel according to claim 1, wherein the small display panel displays the signal receiving status of the notebook computer during wireless communication.

5. A notebook computer with a small display panel according to claim 1, wherein the small display panel displays the battery capacity of the notebook computer.
